(19) United States
(12) Patent Application Publication
(10) Pub. No.: US 2024/0247373 A1
(43) Pub. Date: Jul. 25, 2024

(54) ADJUSTABLE CROSS-FLOW PROCESS CHAMBER LID

(71) Applicant: Applied Materials, Inc., Santa Clara, CA (US)

(72) Inventors: Muhannad Mustafa, Milpitas, CA (US); Sanjeev Baluja, Campbell, CA (US)

(73) Assignee: Applied Materials, Inc., Santa Clara, CA (US)

(21) Appl. No.: 18/100,326

(22) Filed: Jan. 23, 2023

(51) Int. Cl. C23C 16/455; C23C 16/44; C23C 16/458

(52) U.S. Cl. CPC C23C 16/45517; C23C 16/4408; C23C 16/45576; C23C 16/4584

(57) ABSTRACT

Apparatus and methods for improving deposition uniformity in a cross-flow processing chamber are described. A precursor inlet is configured to allow a cross-flow of precursor from the precursor inlet side of the lid to an exhaust side of the lid opposite a center of the lid from the precursor inlet side. At least one purge gas inlet is in fluid communication with a purge gas channel, the purge gas channel having at least one opening aligned to provide a flow of gas to a center of a substrate in the cross-flow process chamber.

### TECHNICAL FIELD

Embodiments of the disclosure generally relate to semiconductor manufacturing apparatus. In particular, embodiments of the disclosure pertain to adjustable cross-flow processing chambers and methods of use.

### BACKGROUND

During the manufacture of semiconductor devices, many deposition processes are employed, amongst other types of processes. Some of the deposition processes may use a cross-flow process chamber in which a flow of gas is passed across the surface of the substrate from one side of the process chamber to the opposite side of the process chamber. In particular, cross-flow deposition process chambers are often used with chemical vapor deposition (CVD) and atomic layer deposition (ALD) deposition processes.

This cross-flow technique is not a new technique for ALD/CVD applications. The cross-flow technique saturates the mass fraction of precursor, or reactive gas, on the substrate surface. In particular, for plasma-based processes, the cross-flow technique has the benefit of avoiding any gas phase reactions.

During cross-flow deposition, a flow of reactive gas passes across the center of the substrate from one edge of the substrate to an edge of the substrate opposite the center while the substrate is rotating around a central axis of the substrate, or the substrate support. During rotation, the center of the substrate remains at zero relative motion compared to the edges of the substrate. As a result, a thicker film is deposited at the center which is a substantial drawback for this technique.

Accordingly, there is need in the art for apparatus and methods to more uniformly deposit a film on a substrate in a cross-flow deposition process chamber.

### SUMMARY

In some aspects, the techniques described herein relate to a lid for a cross-flow semiconductor manufacturing process chamber, the lid including: a precursor inlet on a precursor inlet side of the lid, the precursor inlet configured to allow a cross-flow of precursor from the precursor inlet side of the lid to an exhaust side of the lid opposite a center of the lid from the precursor inlet side; and at least one purge gas inlet on the lid, the purge gas inlet in fluid communication with a purge gas channel having at least one opening aligned to provide a flow of gas to a center of a substrate in the cross-flow process chamber.

In some aspects, the techniques described herein relate to a processing method including: rotating a substrate surface within a processing chamber; flowing a precursor gas parallel to the substrate surface from a first side of a processing chamber to a second side of the processing chamber opposite the first side relative to a center of the substrate surface; and flowing a purge gas orthogonal to the precursor gas flow to dilute an amount of precursor at the center of the substrate surface.

In some aspects, the techniques described herein relate to a cross-flow process chamber including: a chamber body having at least one sidewall and a bottom; a lid on the chamber body enclosing a process volume; a substrate support within the process volume, the substrate support configured to rotate a substrate around a central axis of the substrate support with a surface of the substrate remaining in a process plane; a precursor inlet on a precursor inlet side of the lid, the precursor inlet configured to provide a cross-flow of precursor from the precursor inlet side of the lid to an exhaust side of the lid opposite a center of the lid from the precursor inlet side, the cross-flow of precursor being substantially parallel to the process plane; and at least one purge gas inlet on the lid, the purge gas inlet in fluid communication with a purge gas channel having at least one opening aligned to provide a flow of gas to a center of a substrate in the cross-flow process chamber, the purge gas flowing orthogonal to the process plane.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 shows an isometric view of a cross-flow process chamber with a cutout to reveal a portion of the interior volume chamber according to one or more embodiment of the disclosure;

FIG. 2 shows a schematic cross-sectional view of a cross-flow process chamber according to one or more embodiment of the disclosure;

FIG. 3A illustrates a purge plate on a chamber lid according to one or more embodiments of the disclosure;

FIGS. 3B and 3C illustrate alternate bottom views of the purge plate of FIG. 3A without the chamber lid according to one or more embodiment of the disclosure;

FIG. 3D illustrates a bottom view of an embodiment of the purge plate according to one or more embodiment of the disclosure;

FIG. 3E illustrates a top view of an embodiment of the purge plate according to one or more embodiment of the disclosure;

FIG. 4A illustrates a purge plate on a chamber lid according to one or more embodiment of the disclosure;

FIGS. 4B and 4C illustrate alternate bottom views of the purge plate of FIG. 4A without the chamber lid according to one or more embodiment of the disclosure;

FIGS. 5A and 5B illustrate bottom views of purge plates according to one or more embodiments of the disclosure;

FIG. 6 shows a flowchart of a processing method according to one or more embodiments of the disclosure; and

FIG. 7 shows a cross-sectional schematic view of a portion of a cross-flow process chamber showing gas flows according to one or more embodiment of the disclosure.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

As used in this specification and the appended claims, the term “substrate” refers to a surface, or portion of a surface, upon which a process acts. It will also be understood by those skilled in the art that reference to a substrate can also refer to only a portion of the substrate, unless the context clearly indicates otherwise. Additionally, reference to depositing on a substrate can mean both a bare substrate and a substrate with one or more films or features deposited or formed thereon

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal, UV cure, e-beam cure and/or bake the substrate surface. In addition to film processing directly on the surface of the substrate itself, in the present disclosure, any of the film processing steps disclosed may also be performed on an underlayer formed on the substrate as disclosed in more detail below, and the term “substrate surface” is intended to include such underlayer as the context indicates.

One or more embodiments of the disclosure advantageously implement an adjustable technique for thickness uniformity improvement from center to edge at cross-flow process chambers during ALD/CVD process. Some embodiments advantageously provide an inert gas (e.g., Ar) flow from center to edge of the substrate by diluting the precursor concentration in a substrate center-focused manner. Some embodiments advantageously allow for the control of an adjustable thickness profile on the substrate. Some embodiments provide a fixed adjusted design and/or in-situ adjusting through flow rate change.

One or more embodiments of the disclosure add a purge plate with variable holes and multiple flow delivery options. The center to edge deposition thickness in some embodiments can be tuned by inert gas (e.g., Ar) dilution of the precursor by adjusting the mass flow rate. In some embodiments, variable holes provide a fixed adjustment to add vertical (relative to a substrate surface being horizontal) inert gas flow rate to the substrate surface.

In some embodiments, the substrate is placed on a pedestal that is rotating either continuously or in variable indexed amounts during the deposition process. Some embodiments take advantage of the substrate center remaining at fixed relative motion compared to the outer portion of the substrate so that inert gas dilution can be higher at the center to compensate for variable precursor mass fraction on the substrate surface. In some embodiments, variable delivery allows for the adjustment of the thickness profile on the substrate surface.

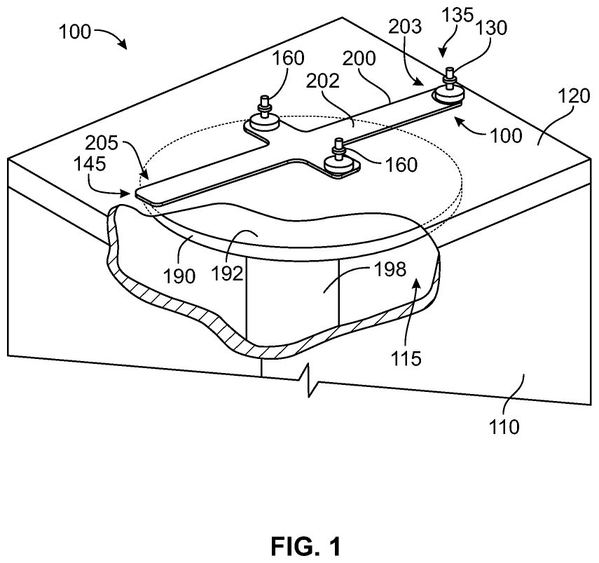

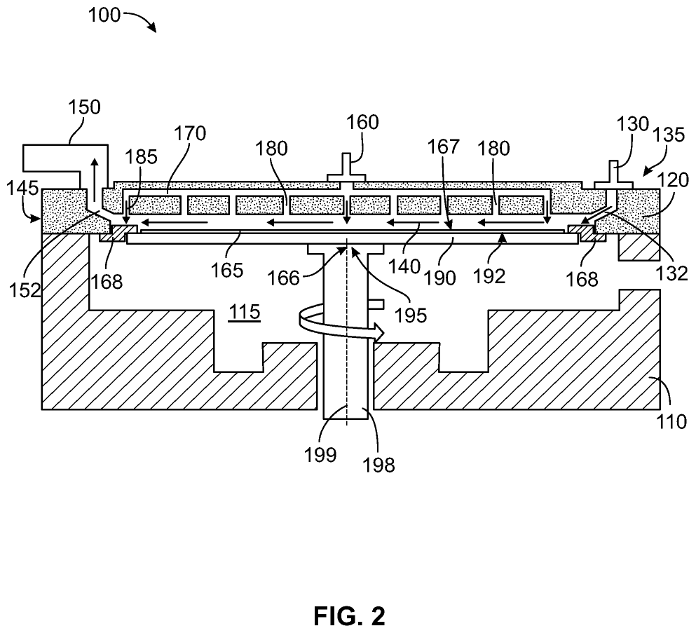

Referring to FIGS. 1 and 2, one or more embodiments of the disclosure are directed to a cross-flow semiconductor process chamber, referred to as a cross-flow process chamber 100. The cross-flow process chamber 100 comprises a chamber body 110 having at least one sidewall and a bottom, and a chamber lid 120 enclosing an interior volume 115. FIG. 1 shows an isometric view of a cross-flow process chamber 100 with a cutout to reveal a portion of the interior volume 115 chamber. FIG. 2 shows a schematic cross-sectional view of a cross-flow process chamber 100.

The cross-flow process chamber 100 includes a substrate support 190 in the interior volume 115. The substrate support 190 has a support surface 192 configured to support a substrate 165 during processing. The substrate support 190 is attached to a support shaft 198 configured to rotate the substrate support 190 around a central axis 199. During rotation, the surface of the substrate remains in a process plane. For the purposes of this description, the center 166 of the substrate 165 is considered to be aligned with the central axis 199 of the substrate support 190. The skilled artisan will recognize that the exact placement of the substrate 165 on the substrate support 190 may be mis-aligned with the central axis 199 and the center 166 is considered to be portion of the substrate 165 aligned with the central axis 199. In the embodiment illustrated in FIG. 2, an edge ring 168 is positioned adjacent to the substrate support 190 to prevent process gas (e.g., precursor) from the precursor inlet 130 from entering the interior volume 115 of the cross-flow process chamber 100.

The chamber lid 120 comprises a precursor inlet 130 on a precursor inlet side 135 of the chamber lid 120. The precursor inlet 130 is configured to allow a cross-flow 140 of precursor (also referred to as process gas) from the precursor inlet side 135 through inlet channel 132 to an exhaust port 150 through exhaust channel 152 on the exhaust side 145 of the chamber lid 120, as shown in FIG. 2. The exhaust side 145 of the chamber lid 120 is located on an opposite side of the center of the chamber lid 120 from the precursor inlet side 135.

The chamber lid 120 includes at least one purge gas inlet 160. The least one purge gas inlet 160 is in fluid communication with a purge gas channel 170. The purge gas channel 170 has at least one opening 180 configured to provide a flow 185 of gas from the purge gas channel 170 to the interior volume 115 of the cross-flow process chamber 100. In some embodiments, the at least one opening 180 is aligned to provide the flow 185 of gas to a center 65 of a substrate 60 in the interior volume 115 of the cross-flow process chamber 100. Stated differently, in some embodiments, the at least one opening 180 is configured to provide the flow 185 of gas to a center 195 of a substrate support 190 in the interior volume 115 of the cross-flow process chamber 100. In some embodiments, the at least one opening 180 is aligned to provide a flow 185 of gas orthogonal to the cross-flow 140 of precursor, as discussed further below.

The inlet channel 132, exhaust channel 152, purge gas channel 170 and at least one opening 180 in some embodiments are formed integrally with the chamber lid 120. In some embodiments, the inlet channel 132, exhaust channel 152 and at least one opening 180 are formed in the chamber lid 120 and the purge gas channel 170 is formed in a separate purge plate 200 aligned with the at least one opening 180. In some embodiments, the purge gas channel 170 is formed as a cavity between the purge plate 200 and the chamber lid 120. In some embodiments, as shown in FIG. 1, a purge plate 200 is connected to the chamber lid 120. The at least one purge gas inlet 160 is connected to and in fluid communication with a purge gas channel 170 in the purge plate 200.

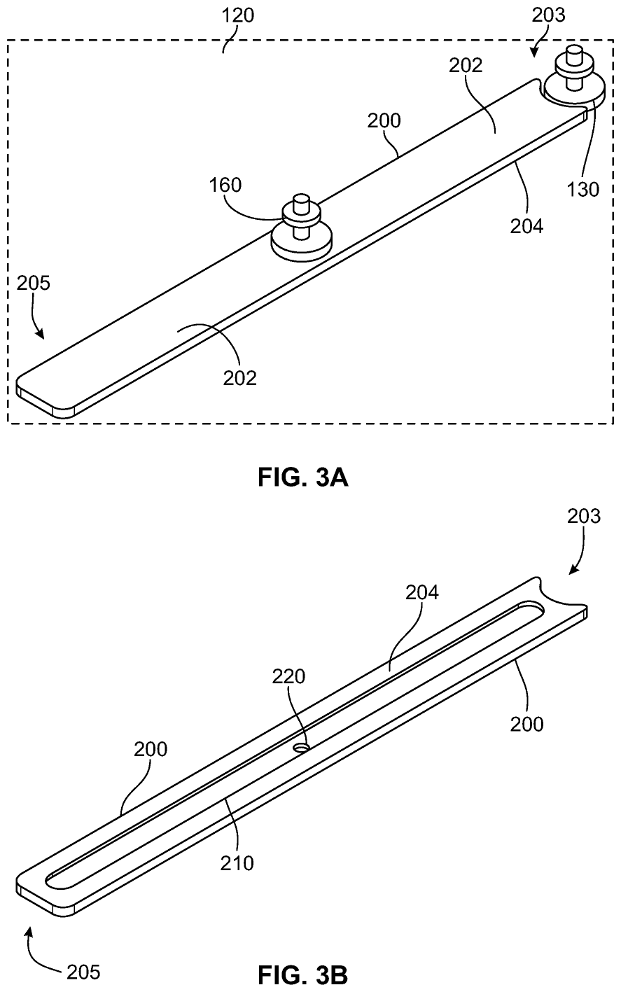

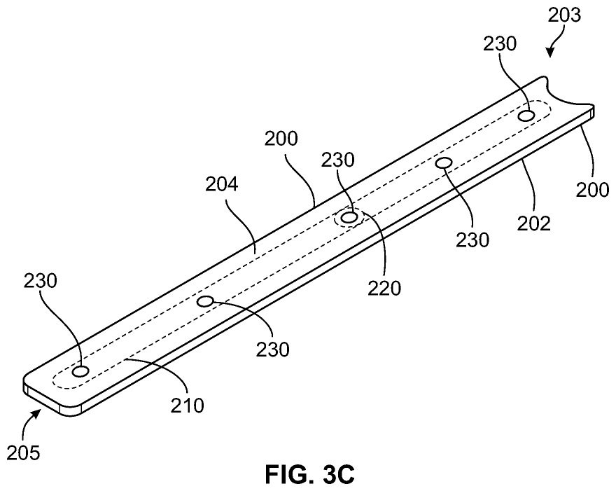

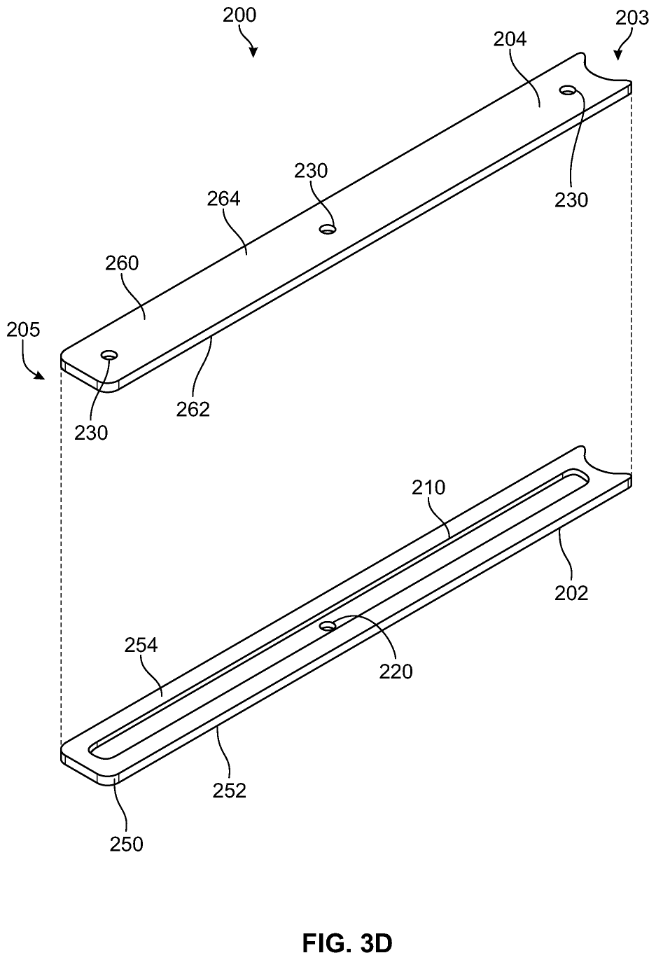

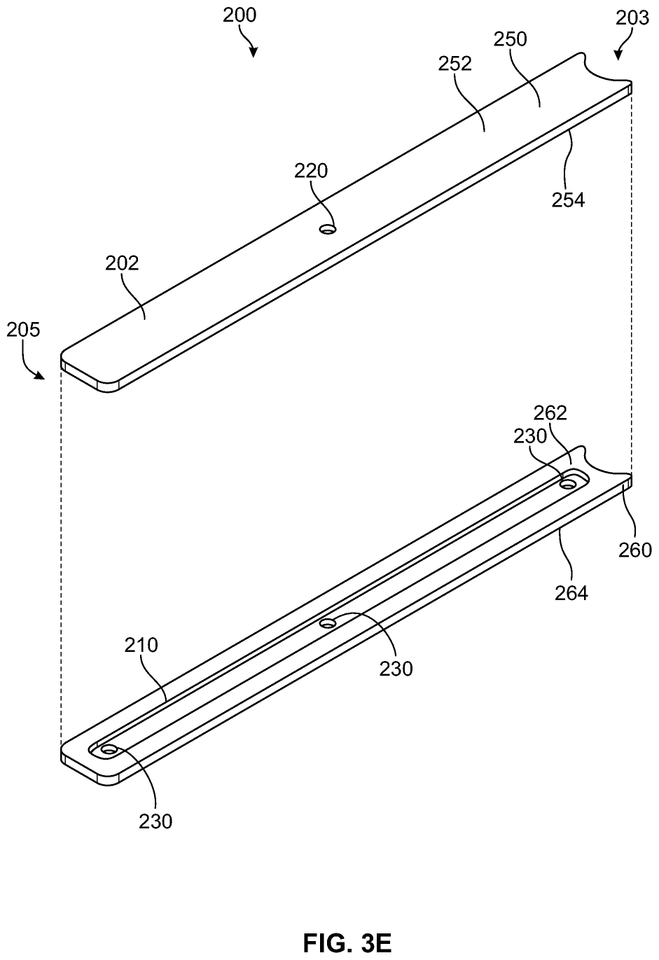

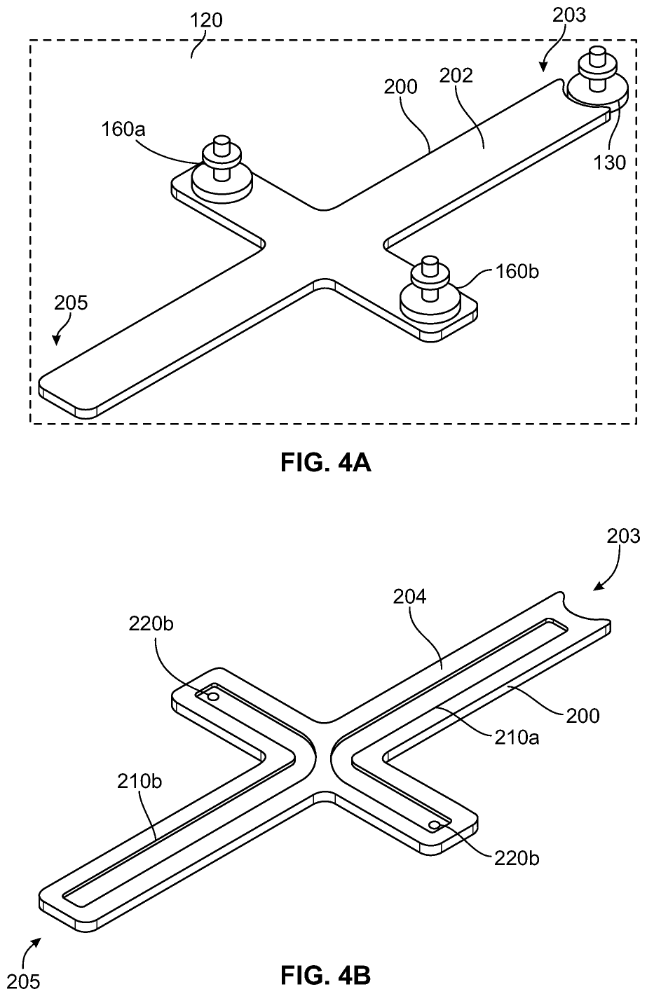

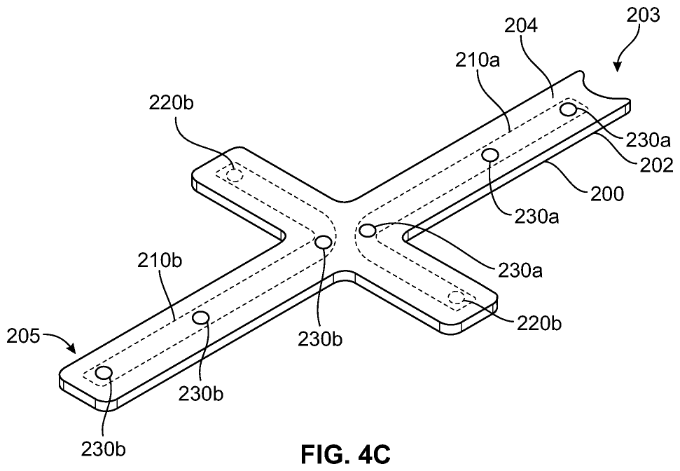

FIG. 3A illustrates a purge plate 200 on a chamber lid 120 according to one or more embodiments of the disclosure. FIGS. 3B and 3C illustrate alternate bottom views of the purge plate 200 of FIG. 3A without the chamber lid 120. FIG. 4A illustrates a purge plate 200 on a chamber lid 120 according to another embodiment of the disclosure. FIGS. 4B and 4C illustrate alternate bottom views of the purge plate 200 of FIG. 4A without the chamber lid 120.

In FIG. 3B, the purge plate 200 has a top surface 202 and a bottom surface 204 that define a thickness of the purge plate 200. A channel 210 is formed in the bottom surface 204 of the purge plate 200. The channel 210 is in fluid communication with an opening 220 in the purge plate 200. The opening 220 is configured to align with the at least one purge gas inlet 160.

In FIG. 3C, the purge plate 200 has a top surface 202 and a bottom surface 204 that define a thickness of the purge plate 200. A channel 210 is formed within the interior of the purge plate 200 and is shown in dotted lines. An opening 220 (shown in dotted lines) in the top surface 202 of the purge plate 200 is configured to align with the at least one purge gas inlet 160. At least one opening 230 is formed in the bottom surface 204 of the purge plate 200. The at least one opening 230 is aligned with the channel 210 formed within the thickness of the purge plate 200.

FIG. 3D illustrates a bottom view of an embodiment of the purge plate 200 combining aspects of the embodiments shown in FIGS. 3B and 3C. The purge plate 200 illustrated in FIG. 3D is a lamination of two components; a back plate 250 and a front plate 260. The back plate 250 has a top surface 252 and a bottom surface 254. A channel 210 is formed in the bottom surface 254 of the back plate 250. At least one opening 220 is formed in the back plate 250 aligned with the channel 210 and configured to be aligned with the at least one purge gas inlet 160. The front plate 260 has a top surface 262 and a bottom surface 264. The front plate 260 can be connected to the back plate 250 so that the top surface 262 of the front plate 260 is in contact with the bottom surface 254 of the back plate 250. At least one opening 230 is formed in the front plate 260 and is configured to align with the channel 210 formed in the back plate 250. When assembled in this manner, the combination of the back plate 250 and front plate 260 form a purge plate 200 that appears as that shown in FIG. 3C.

FIG. 3E illustrates a top view of an embodiment of the purge plate 200 combining aspects of the embodiments shown in FIGS. 3B and 3C. The purge plate 200 illustrated in FIG. 3E is a lamination of two components; a back plate 250 and a front plate 260. The back plate 250 has a top surface 252 and a bottom surface 254. The front plate 260 has a top surface 262 and a bottom surface 264 defining a thickness of the front plate 260. A channel 210 is formed in the top surface 262 of the front plate 260. At least one opening 220 extends through the thickness of the back plate 250 and is aligned with the at least one purge gas inlet 160 and the channel 210 formed in the front plate 260. At least one opening 230 is aligned with the channel 210 in the front plate 260 and extends to the bottom surface 264 of the front plate 260. When assembled in this manner, the combination of the back plate 250 and the front plate 260 form a purge plate 200 that appears as that shown in FIG. 3C.

The front plate 260 and back plate 250 can be connected by any suitable technique known to the skilled artisan. For example, the front plate 260 and back plate 250 can be welded to form a single component purge plate 200.

Referring back to FIG. 3C, in some embodiments, the purge plate 200 comprises at least two openings 230 forming fluid communication between the channel 210 and the bottom surface 204 of the purge plate 200. One opening 230 is located adjacent to a first end 203 of the purge plate 200 and one opening is located at a second end 205 of the purge plate 200. In the embodiment illustrated, there are a total of five openings 230 formed to provide fluid communication between the channel 210 and the bottom surface 204. When positioned on the lid 120, a center opening 230 is located over the central axis 199 of the substrate support 190. The at least one opening 230 is aligned with the cross-flow 140 of reactive gas so that an inert gas exiting the at least one opening 230 flow orthogonal to the cross-flow 140 of reactive gas.

The embodiment illustrated in FIGS. 4A-4C differs from those of FIGS. 3A-3C, respectively, because there is more than one purge gas inlet 160 and channel 210. In FIG. 4B, the purge plate 200 has a top surface 202 and a bottom surface 204 that define a thickness of the purge plate 200. A first channel 210a and a second channel 210b are formed in the bottom surface 204 of the purge plate 200. The first channel 210a and second channel 210b are in fluid communication with a first opening 220a and a second opening 220b, respectively, in the purge plate 200. The first opening 220a is configured to align with the a first gas inlet 160a, and the second opening 220b is configured to align with a second gas inlet 160b.

In FIG. 4C, the purge plate 200 has a top surface 202 and a bottom surface 204 that define a thickness of the purge plate 200. A first channel 210a and a second channel 210b are formed within the interior of the purge plate 200 and are shown in dotted lines. A first opening 220a (shown in dotted lines) and a second opening 220b (shown in dotted lines) in the top surface 202 of the purge plate 200 are configured to align with the first purge gas inlet 160a and the second purge gas inlet 160b, respectively. At least one opening 230 is formed in the bottom surface 204 of the purge plate 200. As shown, at least one first opening 230a is aligned with the first channel 210a, and at least one second opening 230b is aligned with the second channel 210b.

The embodiments illustrated in FIGS. 4A through 4C can be constructed in a similar manner to those of FIGS. 3A through 3C. For example, a lamination of the back plate 250 and front plate 260, similar to those illustrated in FIGS. 3D and 3E, can be used. The skilled artisan will recognize how to prepare the purge plate 200 using the back plate 250 and front plate 260 lamination with the appropriate shaped channels.

Referring again to FIGS. 4A through 4C, in some embodiments, there are two purge gas inlets 160 on the purge plate 200. One purge gas inlet 160a is connected to an inlet purge gas channel (first channel 210a) having at least one opening 230a adjacent the precursor inlet 130 at the precursor inlet side 135 of the chamber lid 120. One purge inlet 160b is connected to an exhaust purge gas channel (second channel 210b) having at least one opening 230b adjacent the exhaust side 145 of the lid 120.

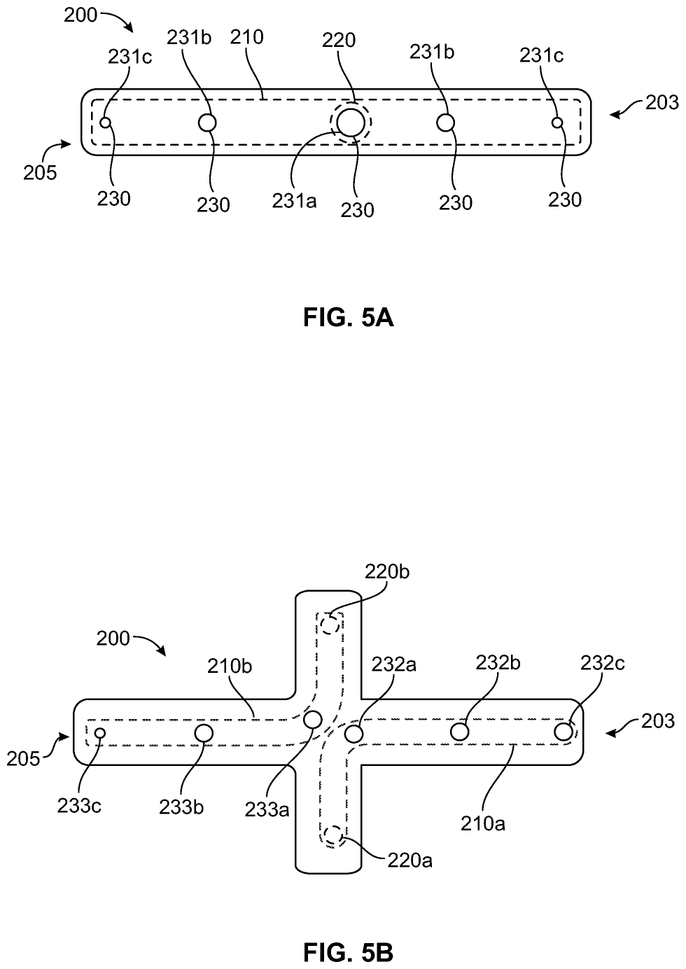

FIGS. 5A and 5B illustrate bottom views of purge plates 200 according to one or more embodiments of the disclosure. In FIG. 5A, a single inlet opening 220 is in fluid communication with a single channel 210 (both shown in dotted lines). A plurality of openings 230 are formed along the length of the channel 210. The diameter of the individual openings 230 change with position along the length of the channel 210. The largest diameter opening 231a is located in the center of the channel 210, which would be aligned with the central axis 199 of the substrate support 190 when in use. The diameters of the openings 231b are smaller than the diameter of opening 231a, and the diameter of the openings 231c are smaller than the diameter of the openings 231b so that there is a diameter gradient extending from the center of the channel 210 to the outer ends of the channel 210.

In FIG. 5B, a first opening 220a is in fluid communication with a first channel 210a (also referred to as the inlet purge gas channel), and a second opening 220b is in fluid communication with a second channel 210b (also referred to as the exhaust purge gas channel). The term “inlet purge gas channel” refers to the channel 210 formed with openings closest to the precursor inlet 130 and the term “exhaust purge gas channel” refers to the channel 210 formed with openings closest to the exhaust port 150 or exhaust side 145 of the cross-flow process chamber 100. The diameters of the openings 230 in each of the channels 210 are varied from the largest diameter near the center of the substrate support 190 and the smallest diameter near the opposite end of the channel. For example, the diameter of opening 232a in first channel 210a is larger than the diameter of opening 232b, which is larger than the diameter of opening 232c. Similarly, the diameter of opening 233a in the second channel 210b is larger than the diameter of opening 233b, which is larger than the diameter of opening 233c. The diameters of the openings form a gradient with the largest diameter near the center of the substrate support 190 and the smallest diameters near the opposite ends of the respective channels. Stated differently, the diameter of the openings closer to the purge gas inlets are larger than the diameters of the openings furthest from the purge gas inlets for any given channel.

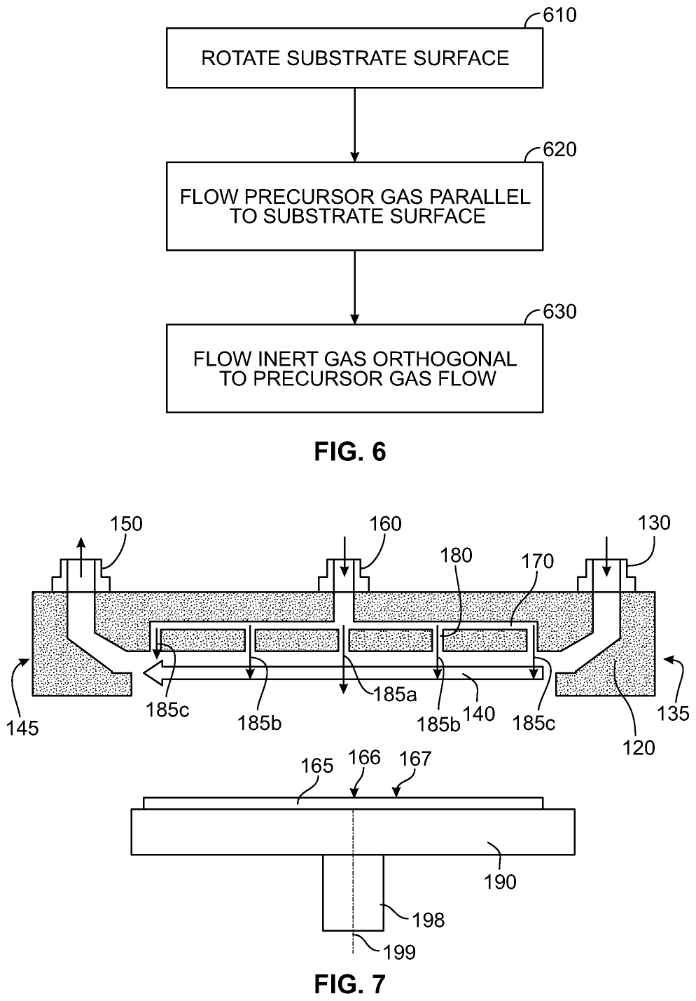

One or more embodiments of the disclosure are directed to processing methods. FIG. 6 shows a flowchart of a processing method 600 according to one or more embodiments of the disclosure. FIG. 7 shows a cross-sectional schematic view of a portion of a cross-flow process chamber 100 showing gas flows. The spacing between the various components illustrated in FIG. 7 are exaggerated for descriptive purposes and should not be taken as limiting the scope of the disclosure. The method 600 is described with reference to FIGS. 2, 6 and 7.

At operation 610, a substrate 165 is positioned on the support surface 192 of a substrate support 190. The substrate support 190 is rotated within the cross-flow process chamber 100 so that the substrate surface 167 rotates around the central axis 199 of the support shaft 198. During rotation, the substrate surface 167 remains in a process plane that is generally parallel to the chamber lid 120. The process plane is defined as the plane formed by the substrate surface 167.

At operation 620, a precursor gas is flowed parallel to the substrate surface 167 from a precursor inlet side 135 (first side) of cross-flow process chamber 100 to an exhaust side 145 (second side) of the cross-flow process chamber 100. The exhaust side 145 is opposite the precursor inlet side 135 of the cross-flow process chamber 100 relative to a center 166 of the substrate surface 167. Stated differently, in some embodiments, the cross-flow of precursor gas is substantially parallel to the process plane. As used in this manner, the term “substantially parallel” means that the flow of precursor gas moves in a generally linear fashion along a direction that is within ±10°, or ±5° of being parallel to the substrate surface, where an angle of 0° is parallel.

At operation 630, a flow 185 of purge gas is directed orthogonal to the cross-flow 140 of precursor gas to dilute an amount of precursor at the center 166 of the substrate surface 167. The flow 185 of purge gas occurs using the chamber lid 120 or the purge plate 200 on the chamber lid 120, as described above with respect to FIGS. 1-5B.

In some embodiments, the flow 185 of purge gas is greatest at the center 166 of the substrate surface 167. Referring to FIG. 7, flow 185a is illustrated as a vector with greater magnitude than the vector representing flow 185b, and flow 185b is illustrated as a vector with greater magnitude than the vector representing flow 185c at the outer edges of the flow path. The magnitude of the flows through the various openings 180 in the chamber lid 120 can be affected by several factors including, but not limited to, the number of openings 180 and the diameters of the individual openings 180.

The purge gas flow 185 of some embodiments compensates for different precursor mass fraction on the substrate surface 167 due to rotation of the substrate support 190. The purge gas flow 185 is adjustable to compensate for different precursor mass fractions. The purge gas flow 185 of some embodiments is delivered as a constant flow. As used in this manner, a “constant” flow means that the flow rate does not vary by more than 10% of the average flow rate through any given opening 180. In some embodiments, the purge gas flow 185 is varied during the precursor flow over time. For example, the purge gas may be pulsed through the at least one opening 180.

In some embodiments, the substrate support 190 is rotated at a constant rate during the method 600. In some embodiments, the substrate support 190 is rotated in discrete intervals with a pause between the intervals.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

Although the disclosure herein has been described with reference to particular embodiments, those skilled in the art will understand that the embodiments described are merely illustrative of the principles and applications of the present disclosure. It will be apparent to those skilled in the art that various modifications and variations can be made to the method and apparatus of the present disclosure without departing from the spirit and scope of the disclosure. Thus, the present disclosure can include modifications and variations that are within the scope of the appended claims and their equivalents.

What is claimed is:

1. A lid for a cross-flow semiconductor process chamber, the lid comprising:
a precursor inlet on a precursor inlet side of the lid, the precursor inlet configured to allow a cross-flow of precursor from the precursor inlet side of the lid to an exhaust side of the lid opposite a center of the lid from the precursor inlet side; and
at least one purge gas inlet on the lid, the at least one purge gas inlet in fluid communication with a purge gas channel having at least one opening aligned to provide a flow of gas to a center of a substrate in the cross-flow semiconductor process chamber.

2. The lid of claim 1, wherein the at least one purge gas inlet is connected to a purge plate, the purge plate connected to the lid.

3. The lid of claim 2, wherein the purge plate further comprises at least two openings, one opening at a first end of the purge plate and one opening at a second end of the purge plate.

4. The lid of claim 2, wherein each of the openings in the purge plate are aligned with the cross-flow of precursor.

5. The lid of claim 2, wherein there are two purge gas inlets on the purge plate, one purge inlet connected to an inlet purge gas channel having at least one opening adjacent the precursor inlet, one purge inlet connected to an exhaust purge gas channel having at least one opening adjacent the exhaust side of the lid.

6. The lid of claim 5, wherein the openings in each of the inlet purge gas channel and exhaust purge gas channel change in diameter with a largest diameter opening in each of the gas channels closer to the purge gas inlet.

7. A processing method comprising:
rotating a substrate surface within a processing chamber;
flowing a precursor gas parallel to the substrate surface from a first side of a processing chamber to a second side of the processing chamber opposite the first side relative to a center of the substrate surface; and
flowing a purge gas orthogonal to the precursor gas flow to dilute an amount of precursor at the center of the substrate surface.

8. The method of claim 7, wherein the purge gas is flowed through a purge plate on a lid of a processing chamber, the purge plate having a purge gas inlet and a purge gas channel having at least one opening aligned with the precursor gas flow.

9. The method of claim 8, wherein the purge plate further comprises at least two openings, one opening at a first end of the purge plate and one opening at a second end of the purge plate.

10. The method of claim 8, wherein the openings in the purge plate are aligned with a cross-flow of precursor.

11. The method of claim 8, wherein there are two purge gas inlets on the purge plate, one purge inlet connected to an inlet purge gas channel having at least one opening adjacent the precursor inlet, one purge inlet connected to an exhaust purge gas channel having at least one opening adjacent an exhaust side of the lid.

12. The method of claim 11, wherein the openings in each of the inlet purge gas channel and the exhaust purge gas channel change in diameter with a largest diameter opening in each of the gas channels closer to the purge gas inlet.

13. The method of claim 8, wherein the flow of purge gas is greatest at the center of the substrate surface.

14. The method of claim 13, wherein the purge gas flow compensates for different precursor mass fraction on a wafer surface.

15. The method of claim 8, wherein the purge gas flow is delivered as a constant flow.

16. The method of claim 8, wherein the purge gas flow is varied during the precursor flow over time.

17. A cross-flow process chamber comprising:
a chamber body having at least one sidewall and a bottom;
a lid on the chamber body enclosing a process volume;
a substrate support within the process volume, the substrate support configured to rotate a substrate around a central axis of the substrate support with a surface of the substrate remaining in a process plane;
a precursor inlet on a precursor inlet side of the lid, the precursor inlet configured to provide a cross-flow of precursor from the precursor inlet side of the lid to an exhaust side of the lid opposite a center of the lid from the precursor inlet side, the cross-flow of precursor being substantially parallel to the process plane; and
at least one purge gas inlet on the lid, the purge gas inlet in fluid communication with a purge gas channel having at least one opening aligned to provide a flow of gas to a center of a substrate in the cross-flow process chamber, the purge gas flowing orthogonal to the process plane.

18. The process chamber of claim 17, wherein the at least one purge gas inlet is connected to a purge plate, the purge plate connected to the lid.

19. The process chamber of claim 18, wherein the purge plate further comprises at least two openings, one opening at a first end of the purge plate and one opening at a second end of the purge plate.

20. The process chamber of claim 18, wherein the openings in the purge plate are aligned with the cross-flow of precursor.
